(19) United States
(12) Patent Application Publication
(10) Pub. No.: US 2026/0040686 A1
(43) Pub. Date: Feb. 5, 2026

(54) DISPLAY APPARATUS, ELECTRONIC APPARATUS, AND METHOD OF MANUFACTURING DISPLAY APPARATUS

(71) Applicant: Samsung Display Co., LTD., Yongin-si (KR)

(72) Inventor: Keunwoo Kim, Yongin-si (KR)

(21) Appl. No.: 19/051,671

(22) Filed: Feb. 12, 2025

(30) Foreign Application Priority Data
Jul. 30, 2024 (KR) 10-2024-0101120

(51) Int. Cl. H10D 86/40; H01L 25/16; H10D 86/01; H10D 86/60; H10H 29/01; H10H 29/32

(52) U.S. Cl. CPC H10D 86/421; H01L 25/167; H10D 86/0229; H10D 86/60; H10H 29/012; H10H 29/32

(57) ABSTRACT

Provided is a display apparatus including a substrate, a first transistor on the substrate and including a first active pattern including a silicon semiconductor, and a gate insulating layer on the first active pattern, wherein the first active pattern includes a first region, a second region, and a third region between the first region and the second region, the third region includes a third-1 region adjacent to the first region and a third-2 region adjacent to the second region, and a first thickness of a portion of the gate insulating layer that overlaps the third-1 region is less than a second thickness of another portion of the gate insulating layer that overlaps the third-2 region.

### CROSS-REFERENCE TO RELATED APPLICATION

This application is based on and claims priority under 35 U.S.C. § 119 to Korean Patent Application No. 10-2024-0101120, filed on Jul. 30, 2024, in the Korean Intellectual Property Office, the entire content of which is hereby incorporated by reference.

### BACKGROUND

### 1. Field

One or more embodiments of the present disclosure relate to a display apparatus and a method of manufacturing the display apparatus. A display apparatus may include a light-emitting diode and a thin-film transistor. An electronic apparatus may include the display apparatus.

### 2. Description of the Related Art

Display apparatuses visually display data. Display apparatuses may display images using light-emitting diodes. Light-emitting diodes of display apparatuses may be driven by thin-film transistors connected to the light-emitting diodes. The purpose of display apparatuses has diversified, and various attempts have been made to improve the quality of display apparatuses.

### SUMMARY

One or more embodiments of the present disclosure include a display apparatus including a light-emitting diode driven by thin-film transistors including a silicon semiconductor. One or more embodiments aim to control afterimages remaining on a display apparatus when the display apparatus displays images and is driven for a preset time or more. In embodiments aim to control a threshold voltage of a thin-film transistor that drives a light-emitting diode of a display apparatus. However, these objectives are just examples, and the disclosure is not limited thereto.

Additional aspects of embodiments will be set forth in part in the description which follows and, in part, will be apparent from the description, or may be learned by practice of the presented embodiments of the disclosure.

According to one or more embodiments, a display apparatus includes a substrate, a first transistor on the substrate and including a first active pattern including a silicon semiconductor, and a gate insulating layer on the first active pattern, wherein the first active pattern includes a first region, a second region, and a third region between the first region and the second region, the third region includes a third-1 region adjacent to the first region and a third-2 region adjacent to the second region, and a first thickness of a portion of the gate insulating layer that overlaps the third-1 region is less than a second thickness of another portion of the gate insulating layer overlapping the third-2 region.

In an embodiment, the display apparatus may further include a first gate electrode on the gate insulating layer and that overlaps the third region of the first active pattern.

In an embodiment, a thickness of a portion of the first gate electrode overlapping the third-1 region may be greater than a thickness of another portion of the first gate electrode that overlaps the third-2 region.

In an embodiment, the display apparatus may further include a second transistor on the substrate and including a second active pattern including a silicon semiconductor, wherein the second active pattern may include a fourth region, a fifth region, and a sixth region between the fourth region and the fifth region, the gate insulating layer may overlap the second active pattern, and a portion of the gate insulating layer that overlaps the sixth region may have the second thickness.

In an embodiment, the display apparatus may further include a third transistor on the substrate and including a third active pattern including a silicon semiconductor, wherein the third active pattern may include a seventh region, an eighth region, and a ninth region between the seventh region and the eighth region, the gate insulating layer may overlap the third active pattern, and a portion of the gate insulating layer that overlaps the ninth region may have the first thickness.

In an embodiment, the display apparatus may further include a light-emitting diode on the gate insulating layer, wherein the second region of the first active pattern may be connected to the light-emitting diode.

In an embodiment, a concentration of hydrogen ions inside the first active pattern in the third-1 region may be greater than a concentration of hydrogen ions inside the first active pattern in the third-2 region.

In an embodiment, the substrate may include a display area and a non-display area that surrounds the display area, the first transistor may be in the display area, the display apparatus may include at least one driving circuit transistor in the non-display area and including a driving circuit active pattern including a silicon semiconductor, the gate insulating layer may partially have the second thickness in a region that overlaps the driving circuit active pattern of the driving circuit transistor.

In an embodiment, the driving circuit active pattern of the driving circuit transistor may include a first conductive area, a second conductive area, and an intermediate area between the first conductive area and the second conductive area, and the gate insulating layer may have the second thickness in a region that overlaps the intermediate area.

According to one or more embodiments, an electronic apparatus includes a display apparatus, and a housing accommodating the display apparatus, wherein the display apparatus includes a substrate, a first transistor on the substrate and including a first active pattern including a silicon semiconductor, and a gate insulating layer on the first active pattern, wherein the first active pattern includes a first region, a second region, and a third region between the first region and the second region, the third region includes a third-1 region adjacent to the first region and a third-2 region adjacent to the second region, and a first thickness of a portion of the gate insulating layer that overlaps the third-1 region is less than a second thickness of another portion of the gate insulating layer overlapping the third-2 region.

According to one or more embodiments, a method of manufacturing a display apparatus includes providing, on a substrate, a first active pattern including a first region, a second region, and a third region between the first region and the second region, providing a first insulating layer on the first active pattern in a third-2 region of a third-1 region adjacent to the first region and the third-2 region adjacent to the second region, and passivation-treating the first active pattern in the third-1 region.

In an embodiment, the method may further include forming a gate insulating layer by providing a second insulating layer on the first active pattern, wherein the gate insulating layer may include the first insulating layer and the second insulating layer, the gate insulating layer may have a first thickness in the third-1 region, and the gate insulating layer may have a second thickness in the third-2 region.

In an embodiment, the second insulating layer may have the first thickness, the first insulating layer may have a third thickness, and the second thickness may be a sum of the first thickness and the third thickness.

In an embodiment, the first insulating layer and the second insulating layer may include a same material.

In an embodiment, the method may further include providing, on the substrate, a second active pattern including a fourth region, a fifth region, and a sixth region between the fourth region and the fifth region, wherein the first insulating layer may overlap the sixth region of the second active pattern.

In an embodiment, the providing of the first insulating layer may include providing a preliminary layer to cover the first active pattern entirely, providing a photoresist to overlap the third-2 region, and etching the preliminary layer using the photoresist as a mask.

In an embodiment, the passivation-treating of the first active pattern may include irradiating hydrogen plasma toward the first active pattern, wherein the first insulating layer may prevent the hydrogen plasma from reaching the first active pattern in the third-2 region (or reduce an amount of the hydrogen plasma that reaches the first active pattern in the third-2 region).

In an embodiment, after the passivation-treating of the first active pattern is performed, a concentration of hydrogen ions inside the first active pattern in the third-1 region may be greater than a concentration of hydrogen ions inside the first active pattern in the third-2 region.

In an embodiment, the substrate may include a display area and a non-display area surrounding the display area, the first active pattern may be in the display area, and the method may further include providing a driving circuit active pattern including a silicon semiconductor in the non-display area, wherein the first insulating layer may at least partially overlap the driving circuit active pattern.

In an embodiment, the method may further include forming a light-emitting diode on the substrate, wherein the light-emitting diode may be electrically connected to the second region of the first active pattern.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a schematic plan view of an electronic apparatus according to an embodiment;

FIG. 2 is an equivalent circuit diagram of a sub-pixel of a display area of a display apparatus according to an embodiment;

FIG. 3 is a cross-sectional view of a display apparatus according to an embodiment.

FIG. 4 is a cross-sectional view of the display apparatus according to an embodiment;

FIG. 5 is an enlarged cross-sectional view of a display apparatus according to an embodiment;

FIG. 6 is an enlarged cross-sectional view of a portion of a display apparatus according to an embodiment;

FIG. 7 is an enlarged cross-sectional view of a portion of a display apparatus according to an embodiment;

FIG. 8 is a schematic plan view of a display apparatus according to an embodiment;

FIG. 9 is an enlarged cross-sectional view of a portion of a display apparatus according to an embodiment; and

FIGS. 10A, 10B, 10C, 10D, 10E, and 10F are schematic cross-sectional views showing a method of manufacturing a display apparatus, according to an embodiment.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of embodiments of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various suitable changes and numerous embodiments, certain embodiments will be illustrated in the drawings and described in the written description. Effects and features of the subject matter of the disclosure, and methods for achieving them will be clarified with reference to embodiments described below with reference to the drawings. However, the subject matter of the disclosure is not limited to the following embodiments and may be embodied in various suitable forms.

When description is made with reference to the drawings, the same reference numerals are given to the same or corresponding elements and repeated descriptions thereof are omitted.

While such terms as “first” and “second” may be used to describe various components, such components must not be limited to the above terms. The above terms are used to distinguish one component from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

It will be further understood that, when a layer, region, or component is referred to as being “on” another layer, region, or component, it can be directly or indirectly on the other layer, region, or component. For example, intervening layers, regions, or components may be present.

Sizes of elements in the drawings may be exaggerated or reduced for convenience of explanation. As an example, the size and thickness of each element shown in the drawings may be arbitrarily represented for convenience of description, and thus, the disclosure is not necessarily limited thereto.

In the case where a certain embodiment may be implemented differently, a specific process order may be performed in an order different from the described order. As an example, two processes successively described may be performed concurrently (e.g., simultaneously) or may be performed in the opposite order.

In the present specification, “A and/or B” means A or B, or A and B. In the present specification, “at least one of A and B” means A or B, or A and B.

It will be understood that when a layer, region, or component is referred to as being “connected” to another layer, region, or component, it may be “directly connected” to the other layer, region, or component or may be “indirectly connected” to the other layer, region, or component with other layer, region, or component interposed therebetween.

x, y and z are not limited to three directions of the rectangular coordinate system, and may be interpreted in a broader sense. For example, x, y, and z may be perpendicular to one another, or may represent different orientations that are not perpendicular to one another.

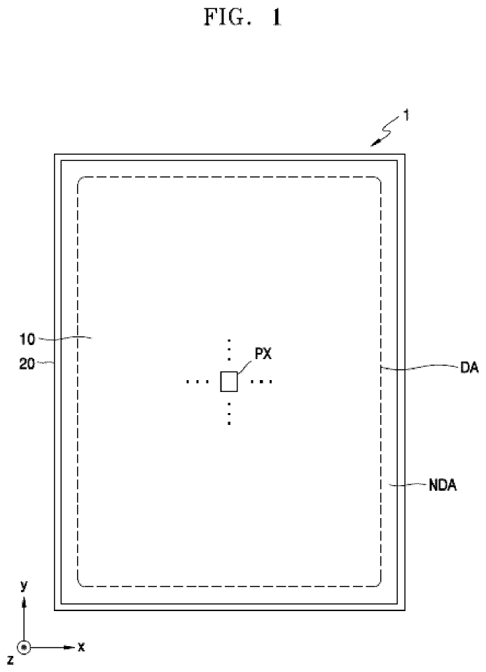

FIG. 1 is a schematic plan view of an electronic apparatus 1 according to an embodiment.

Referring to FIG. 1, the electronic apparatus 1 may include a display apparatus 10 and a housing 20. In an embodiment, the display apparatus 10 may be accommodated in the housing 20.

The electronic apparatus 1 may include various suitable products including televisions, notebook computers, monitors, advertisement boards, and Internet of things (IOT) devices as well as portable electronic apparatuses including mobile phones, smartphones, tablet personal computers (PCs), mobile communication terminals, electronic organizers, electronic books, portable multimedia players (PMPs), navigations, and ultra mobile personal computers (UMPCs). In embodiments, the electronic apparatus 1 may include wearable devices including smartwatches, watchphones, glasses-type displays, and head-mounted displays (HMDs). In embodiments, the electronic apparatus 1 may include a display in instrument panels for automobiles, center fascias for automobiles, and/or center information displays (CIDs) on a dashboard, room mirror displays that replace side mirrors of automobiles, and/or displays of an entertainment system on the backside of front seats for backseat passengers in automobiles. The display apparatus 10 is an element that displays moving images and/or still images in various embodiments of the electronic apparatus 1 and may be included in the electronic apparatus 1.

The display apparatus 10 may include a display area DA and a non-display area NDA outside the display area DA. The display area DA may be configured to display images through sub-pixels PX in the display area DA. The non-display area NDA is provided outside the display area DA and does not display images. The non-display area NDA may surround the display area DA entirely. A driver and/or the like configured to provide electrical signals and/or power to the display area DA may be in the non-display area NDA. A pad may be in the non-display area NDA, wherein the pad is a region to which electronic elements and/or a printed circuit board may be electrically connected.

Although it is shown in FIG. 1 that the display area DA is a quadrangle in which a length thereof in an x direction is less than a length thereof in a y direction, the display area DA may be a quadrangle in which a length thereof in a y direction is less than a length thereof in an x direction in an embodiment. Although it is shown in FIG. 1 that the display area DA is approximately quadrangular, the display area DA may have various suitable shapes such as an N-gon (N is a natural number greater than or equal to 3, N≠4) or a circle (e.g., generally a circle) or an oval (e.g., generally an oval) in an embodiment. Although it is shown in FIG. 1 that the display area DA has a shape in which a corner of the display area DA includes a vertex at which a straight line meets a straight line, the display area DA may have a polygon having round corners in an embodiment.

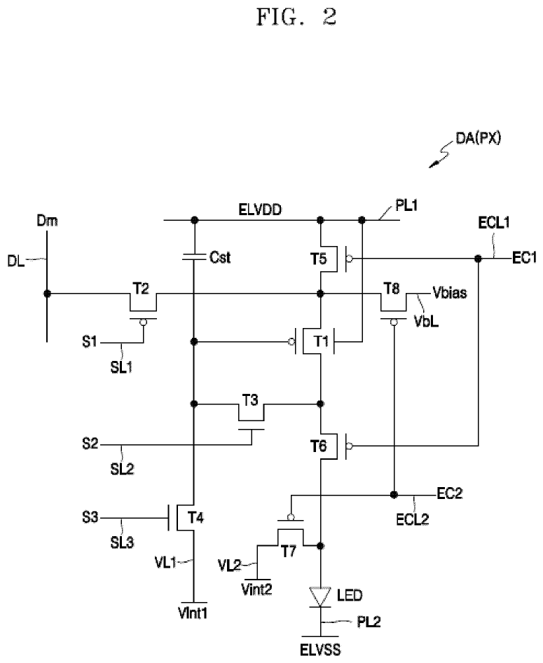

FIG. 2 is an equivalent circuit diagram of the sub-pixel PX of the display area DA of the display apparatus 10 according to an embodiment.

Referring to FIG. 2, the sub-pixel PX may include a light-emitting diode LED and a sub-pixel circuit driving the light-emitting diode LED. The sub-pixel circuit may include a plurality of thin-film transistors. The sub-pixel circuit may be connected to a plurality of lines such as a signal line, a power line, and a voltage line. Some of the lines may be included in a portion of the sub-pixel circuit. The sub-pixel circuit may selectively further include a capacitor.

The sub-pixel circuit may include first to eighth transistors T1, T2, T3, T4, T5, T6, T7, and T8, and a capacitor Cst. The sub-pixel circuit may be connected to the plurality of signal lines, a first voltage line VL1, a second voltage line VL2, a third voltage line VbL, and a first power line PL1. The plurality of signal lines may include a data line DL, a first scan line SL1, a second scan line SL2, a third scan line SL3, a first emission control line ECL1, and a second emission control line ECL2.

The first power line PL1 may transfer a first power voltage ELVDD to the sub-pixel circuit. The first voltage line VL1 may transfer a first voltage Vint1 to the sub-pixel circuit. The second voltage line VL2 may transfer a second voltage Vint2 to the sub-pixel circuit. The third voltage line VbL may transfer a third voltage Vbias to the sub-pixel circuit. The data line DL may transfer a data signal Dm to the sub-pixel circuit. The first scan line SL1 may transfer a first scan signal S1 to the sub-pixel circuit. The second scan line SL2 may transfer a second scan signal S2 to the sub-pixel circuit. The third scan line SL3 may transfer a third scan signal S3 to the sub-pixel circuit. The first emission control line ECL1 may transfer a first emission control signal EC1 to the sub-pixel circuit. The second emission control line ECL2 may transfer a second emission control signal EC2 to the sub-pixel circuit.

The first transistor T1 may be connected to the first power line PL1 through the fifth transistor T5. The first transistor T1 may be connected to the light-emitting diode LED through the sixth transistor T6. A gate of the first transistor T1 may be connected to the third transistor T3, the fourth transistor T4, and the capacitor Cst. In an embodiment, the first transistor T1 may be a driving transistor. The first transistor T1 may receive a data signal Dm and supply a driving current to the light-emitting diode LED according to a switching operation of the second transistor T2.

The second transistor T2 may be connected to the data line DL. The second transistor T2 may be connected to the first transistor T1, the fifth transistor T5, and the eighth transistor T8. A gate of the second transistor T2 may be connected to the first scan line SL1. The second transistor T2 may be a switching transistor. The second transistor T2 may be turned on according to a first scan signal transferred through the first scan line SL1 and may transfer a data signal Dm to the first transistor T1, wherein the data signal Dm is transferred through the data line DL.

The third transistor T3 may be connected to the first transistor T1 and the sixth transistor T6. The third transistor T3 may be connected to the gate of the first transistor T1 and the fourth transistor T4. A gate of the third transistor T3 may be connected to the second scan line SL2. The third transistor T3 may be turned on according to a second scan signal to diode-connect the first transistor T1, wherein the second scan signal is transferred through the second scan line SL2.

The fourth transistor T4 may be connected to the third transistor T3. The fourth transistor T4 may be connected to the first voltage line VL1. A gate of the fourth transistor T4 may be connected to the third scan line SL3. The fourth transistor T4 may be a first initialization transistor. The fourth transistor T4 may be turned on according to a third scan signal S3 transferred through the third scan line SL3 and may transfer the first voltage Vint1 to the gate of the first transistor T1, wherein the first voltage Vint1 is transferred through the first voltage line VL1.

The fifth transistor T5 may be connected to the first transistor T1. The fifth transistor T5 may be connected to the first power line PL1. A gate of the fifth transistor T5 may be connected to the first emission control line ECL1. The fifth transistor T5 may be a first operation control transistor. The fifth transistor T5 may be turned on according to a first emission control signal EC1 transferred through the first emission control line ECL1, and may transfer the first power voltage ELVDD to the first transistor T1, wherein the first power voltage ELVDD is transferred through the first power line PL1.

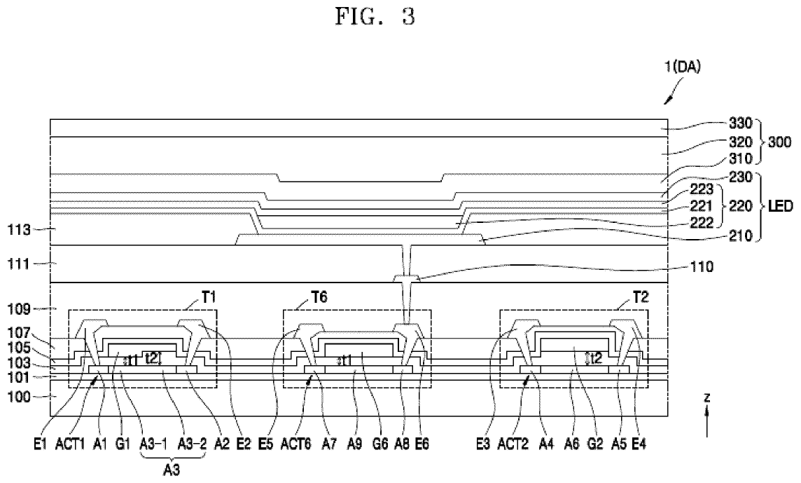

The sixth transistor T6 may be connected to the first transistor T1. The sixth transistor T6 may be connected to the light-emitting diode LED. As an example, a sixth electrode E6 (see FIG. 3) of the sixth transistor T6 may be connected to a sub-pixel electrode 210 (see FIG. 3) of the light-emitting diode LED. A gate of the sixth transistor T6 may be connected to the first emission control line ECL1. The sixth transistor T6 may be a second operation control transistor. The sixth transistor T6 may be turned on according to a first emission control signal EC1 transferred through the first emission control line ECL1 and may connect the first transistor T1 to the light-emitting diode LED.

The seventh transistor T7 may be connected to the light-emitting diode LED through the sixth transistor T6. The seventh transistor T7 may be connected to the second voltage line VL2. A gate of the seventh transistor T7 may be connected to the second emission control line ECL2. The seventh transistor T7 may be a second initialization transistor. The seventh transistor T7 may be turned on according to a second emission control signal EC2 transferred through the second emission control line ECL2, and may transfer the second voltage Vint2 received via the second voltage line VL2 to the light-emitting diode LED, thereby initializing the light-emitting diode LED.

The eighth transistor T8 may be connected to the first transistor T1 and the fifth transistor T5. The eighth transistor T8 may be connected to the third voltage line VbL. A gate of the eighth transistor T8 may be connected to the second emission control line ECL2. The eighth transistor T8 may be turned on according to a second emission control signal EC2 transferred through the second emission control line ECL2 and may transfer the third voltage Vbias to the first transistor T1, wherein the third voltage Vbias is transferred through the third voltage line VbL.

The capacitor Cst may be connected between the gate of the first transistor T1 and the first power line. In an embodiment, the capacitor Cst may be omitted.

The light-emitting diode LED may be connected to the first transistor T1 through the sixth transistor T6. The sub-pixel electrode 210 (see FIG. 3) of the light-emitting diode LED may be connected to the sixth transistor T6, and an opposite electrode 230 (FIG. 3) of the light-emitting diode LED may be connected to the second power line PL2. The light-emitting diode LED may be supplied with the first power voltage ELVDD from the first power line PL1 through the fifth transistor T5, the first transistor T1, and the sixth transistor T6. The light-emitting diode LED may be supplied with a second power voltage ELVSS from the second power line PL2. The light-emitting diode LED may emit light using a current, for example, a driving current due to a potential difference between the first power voltage ELVDD and the second power voltage ELVSS.

In an embodiment, at least one selected from among the first transistor T1, the second transistor T2, the fifth transistor T5, the sixth transistor T6, the seventh transistor T7, and the eighth transistor T8 may include a silicon semiconductor. As an example, at least one selected from among the first transistor T1, the second transistor T2, the fifth transistor T5, the sixth transistor T6, the seventh transistor T7, and the eighth transistor T8 may include a semiconductor layer having low-temperature polycrystalline silicon (LTPS). In an embodiment, at least one selected from among the third transistor T3 and the fourth transistor T4 may include an oxide semiconductor. As an example, at least one selected from among the third transistor T3 and the fourth transistor T4 may include indium gallium zinc oxide (IGZO). The foregoing, however, are just examples, and the material of the first to eighth transistors T1, T2, T3, T4, T5, T6, T7, and T8 may be suitably variously modified.

FIG. 3 is a cross-sectional view of the display apparatus 10 according to an embodiment.

Referring to FIG. 3, the first transistor T1, the second transistor T2, and the sixth transistor T6 may be on the substrate 100. Although the third to fifth transistors T3, T4, and T5, the seventh transistor T7, and the eighth transistor T8 described with reference to FIG. 2 may be on the substrate 100, for convenience of illustration and description, these transistors are omitted.

The substrate 100 may include glass, metal, and/or polymer resin. In embodiments where the display apparatus 10 is flexible and/or bendable, the substrate 100 may include, for example, a polymer resin including polyethersulfone, polyacrylate, polyetherimide, polyethylene naphthalate, polyethylene terephthalate, polyphenylene sulfide, polyarylate, polyimide, polycarbonate, and/or cellulose acetate propionate. The substrate 100 may have a multi-layered structure including two layers including the polymer resin and a layer including an inorganic material therebetween. However, various suitable modifications may be made.

A buffer layer 101 may be on the substrate 100. The buffer layer 101 may include an inorganic insulating material (e.g., an inorganic electrically insulating material). As an example, the buffer layer 101 may include at least one selected from among silicon oxide (SiO₂), silicon nitride (SiNₓ), and silicon oxynitride (SiON). The buffer layer 101 may have a single-layered structure or a multi-layered structure.

A first active pattern ACT1 of the first transistor T1, a second active pattern ACT2 of the second transistor T2, and a sixth active pattern ACT6 of the sixth transistor T6 may be on the substrate 100 (e.g., on the buffer layer 101).

The first active pattern ACT1 may include a first region A1, a second region A2, and a third region A3. The third region A3 may be between the first region A1 and the second region A2. The third region A3 may include a third-1 region A3-1 adjacent to the first region A1, and a third-2 region A3-2 adjacent to the second region A2. In an embodiment, the first region A1 may be a source region, and the second region A2 may be a drain region. In an embodiment, the first region A1 may be a drain region, and the second region A2 may be a source region. In an embodiment, the first region A1 and the second region A2 may be regions doped with impurities (e.g., dopants). In an embodiment, the third region A3 may be a channel region.

The second active pattern ACT2 may include a fourth region A4, a fifth region A5, and a sixth region A6. The sixth region A6 may be between the fourth region A4 and the fifth region A5. In an embodiment, the fourth region A4 may be a source region, and the fifth region A5 may be a drain region. In an embodiment, the fourth region A4 may be a drain region, and the fifth region A5 may be a source region. In an embodiment, the fourth region A4 and the fifth region A5 may be regions doped with impurities (e.g., dopants). In an embodiment, the sixth region A6 may be a channel region.

The sixth active pattern ACT6 may include a seventh region A7, an eighth region A8, and a ninth region A9. The ninth region A9 may be between the seventh region A7 and the eighth region A8. In an embodiment, the seventh region A7 may be a source region, and the eighth region A8 may be a drain region. In an embodiment, the seventh region A7 and the eighth region A8 may be regions doped with impurities (e.g., dopants). In an embodiment, the ninth region A9 may be a channel region.

A first gate insulating layer 103 may cover the first active pattern ACT1, the second active pattern ACT2, and the sixth active pattern ACT6. The first gate insulating layer 103 may include contact holes that respectively overlap the first region A1, the second region A2, the fourth region A4, the fifth region A5, the seventh region A7, and the eighth region A8. The first gate insulating layer 103 may include an inorganic insulating material (e.g., an inorganic electrically insulating material). As an example, the first gate insulating layer 103 may include at least one selected from among silicon oxide (SiO₂), silicon nitride (SiNₓ), and silicon oxynitride (SiON).

The first gate insulating layer 103 may have different thicknesses depending on a portion thereof. A portion of the first gate insulating layer 103 that overlaps the third-1 region A3-1 of the first active pattern ACT1 may have a first thickness t1. A portion of the first gate insulating layer 103 overlapping the third-2 region A3-2 of the first active pattern ACT1 may have a second thickness t2. Accordingly, a portion of the first gate insulating layer 103 that overlaps the third region A3 of the first active pattern ACT1 may have a step difference due to a difference between the first thickness t1 and the second thickness t2. A portion of the first gate insulating layer 103 that overlaps the sixth region A6 of the second active pattern ACT2 may have the second thickness t2. A portion of the first gate insulating layer 103 that overlaps the ninth region A9 of the sixth active pattern ACT6 may have the first thickness t1.

In an embodiment, the first thickness t1 may be less than the second thickness t2. A portion of the first gate insulating layer 103 that overlaps the third-2 region A3-2 of the first active pattern ACT1 may be thicker than a portion of the first gate insulating layer 103 that overlaps the third-1 region A3-1 of the first active pattern ACT1. A portion of the first gate insulating layer 103 that overlaps the sixth region A6 of the second active pattern ACT2 may be thicker than a portion of the first gate insulating layer 103 that overlaps the ninth region A9 of the sixth active pattern ACT6.

In an embodiment, the first thickness t1 may be about 1,200 angstrom (Å) to about 1,450 Å. In an embodiment, the second thickness t2 may be about 1,250 Å to about 1,750 Å. In an embodiment, within the above ranges, the second thickness t2 may be greater than the first thickness t1.

A first gate electrode G1, a second gate electrode G2, and a sixth gate electrode G6 may be on the first gate insulating layer 103. The first gate electrode G1 may overlap the first active pattern ACT1. As an example, the first gate electrode G1 may overlap the third region A3 of the first active pattern ACT1. The second gate electrode G2 may overlap the second active pattern ACT2. As an example, the second gate electrode G2 may overlap the sixth region A6 of the second active pattern ACT2. The sixth gate electrode G6 may overlap the sixth active pattern ACT6. As an example, the sixth gate electrode G6 may overlap the ninth region A9 of the sixth active pattern ACT6.

At least one selected from among the first gate electrode G1, the second gate electrode G2, and the sixth gate electrode G6 may include a conductive material (e.g., an electrically conductive material) such as metal. As an example, at least one selected from among the first gate electrode G1, the second gate electrode G2, and the sixth gate electrode G6 may include at least one selected from among aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and copper (Cu). In an embodiment, at least one selected from among the first gate electrode G1, the second gate electrode G2, and the sixth gate electrode G6 may include a single-layered structure including Mo.

The first gate electrode G1 may have a step difference corresponding to different thicknesses of the first gate insulating layer 103. As an example, a thickness of a portion of the first gate electrode G1 that overlaps the third-1 region A3-1 may be greater than a thickness of another portion of the first gate electrode G1 that overlaps the third-2 region A3-2. In embodiments, a thickness of the first gate electrode G1 in a region where a thickness of the first gate insulating layer 103 is the first thickness t1 may be greater than a thickness of the first gate electrode G1 in a region where a thickness of the first gate insulating layer 103 is the second thickness t2.

A second gate insulating layer 105 may cover the first gate electrode G1, the second gate electrode G2, and the sixth gate electrode G6. The second gate insulating layer 105 may include contact holes that respectively overlap the first region A1, the second region A2, the fourth region A4, the fifth region A5, the seventh region A7, and the eighth region A8. The second gate insulating layer 105 may include an inorganic insulating material (e.g., an inorganic electrically insulating material). As an example, the second gate insulating layer 105 may include at least one selected from among silicon oxide (SiO₂), silicon nitride (SiNₓ), and silicon oxynitride (SiON).

An interlayer insulating layer 107 may cover the second gate insulating layer 105. The interlayer insulating layer 107 may include contact holes respectively that overlaps the first region A1, the second region A2, the fourth region A4, the fifth region A5, the seventh region A7, and the eighth region A8. The interlayer insulating layer 107 may include an inorganic insulating material (e.g., an inorganic electrically insulating material). As an example, the interlayer insulating layer 107 may include at least one selected from among silicon oxide (SiO₂), silicon nitride (SiNₓ), and silicon oxynitride (SiON). The interlayer insulating layer 107 may have a single-layered structure or a multi-layered structure. One or more conductive layers (e.g., electrically conductive layers) may be inside the interlayer insulating layer 107.

A plurality of electrodes may be on the interlayer insulating layer 107.

A first electrode E1 may be on the interlayer insulating layer 107 and may overlap the first region A1 of the first active pattern ACT1. The first electrode E1 may be connected to the first region A1 of the first active pattern ACT1 through a contact hole formed in the first gate insulating layer 103, the second gate insulating layer 105, and the interlayer insulating layer 107.

A second electrode E2 may be on the interlayer insulating layer 107 and may overlap the second region A2 of the first active pattern ACT1. The second electrode E2 may be connected to the second region A2 of the first active pattern ACT1 through a contact hole formed in the first gate insulating layer 103, the second gate insulating layer 105, and the interlayer insulating layer 107.

A third electrode E3 may be on the interlayer insulating layer 107 and may overlap the fourth region A4 of the second active pattern ACT2. The third electrode E3 may be connected to the fourth region A4 of the second active pattern ACT2 through a contact hole formed in the first gate insulating layer 103, the second gate insulating layer 105, and the interlayer insulating layer 107.

A fourth electrode E4 may be on the interlayer insulating layer 107 and may overlap the fifth region A5 of the second active pattern ACT2. The fourth electrode E4 may be connected to the fifth region A5 of the second active pattern ACT2 through a contact hole formed in the first gate insulating layer 103, the second gate insulating layer 105, and the interlayer insulating layer 107.

A fifth electrode E5 may be on the interlayer insulating layer 107 and may overlap the seventh region A7 of the sixth active pattern ACT6. The fifth electrode E5 may be connected to the seventh region A7 of the sixth active pattern ACT6 through a contact hole formed in the first gate insulating layer 103, the second gate insulating layer 105, and the interlayer insulating layer 107. In an embodiment, one selected from among the first electrode E1 and the second electrode E2 may be connected to the fifth electrode E5.

A sixth electrode E6 may be on the interlayer insulating layer 107 and may overlap the eighth region A8 of the sixth active pattern ACT6. The sixth electrode E6 may be connected to the eighth region A8 of the sixth active pattern ACT6 through a contact hole formed in the first gate insulating layer 103, the second gate insulating layer 105, and the interlayer insulating layer 107.

At least one selected from among the first to sixth electrodes E1, E2, E3, E4, E5, and E6 may include a conductive material (e.g., an electrically conductive material) such as metal. As an example, at least one selected from among the first to sixth electrodes E1, E2, E3, E4, E5, and E6 may include at least one selected from among aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and copper (Cu). In an embodiment, at least one selected from among the first to sixth electrodes E1, E2, E3, E4, E5, and E6 may include a multi-layered structure in which titanium (Ti), aluminum (Al), and titanium (Ti) are sequentially provided.

A first organic insulating layer 109 may cover the first to sixth electrodes E1, E2, E3, E4, E5, and E6. The first organic insulating layer 109 may include an organic insulating material (e.g., an organic electrically insulating material). As an example, the first organic insulating layer 109 may include at least one selected from among a general-purpose polymer such as benzocyclobutene, polyimide, hexamethyldisiloxane, polymethylmethacrylate or polystyrene, polymer derivatives having a phenol-based group, an acryl-based polymer, an imide-based polymer, an aryl ether-based polymer, an amide-based polymer, a fluorine-based polymer, a p-xylene-based polymer, and a vinyl alcohol-based polymer. In an embodiment, the first organic insulating layer 109 may include polyimide (PI).

A contact electrode 110 may be on the first organic insulating layer 109. The contact electrode 110 may include, for example, a conductive material (e.g., an electrically conductive material) such as metal. As an example, the contact electrode 110 may include at least one selected from among aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and copper (Cu). In an embodiment, the contact electrode 110 may include a multi-layered structure in which Ti, Al, and Ti are sequentially provided. The contact electrode 110 may be connected to the sixth electrode E6 through a contact hole defined in the first organic insulating layer 109.

A second organic insulating layer 111 may cover the contact electrode 110.

The second organic insulating layer 111 may include an organic insulating material (e.g., an organic electrically insulating material). As an example, the second organic insulating layer 111 may include at least one selected from among a general-purpose polymer such as benzocyclobutene, polyimide, hexamethyldisiloxane, polymethylmethacrylate or polystyrene, polymer derivatives having a phenol-based group, an acryl-based polymer, an imide-based polymer, an aryl ether-based polymer, an amide-based polymer, a fluorine-based polymer, a p-xylene-based polymer, and a vinyl alcohol-based polymer. In an embodiment, the second organic insulating layer 111 may include PI.

The light-emitting diode LED may be on the second organic insulating layer 111. The light-emitting diode LED may include a sub-pixel electrode 210, an intermediate layer 220, and an opposite electrode 230.

The sub-pixel electrode 210 may be on the second organic insulating layer 111. The sub-pixel electrode 210 may include a conductive oxide (e.g., an electrically conductive oxide) including at least one selected from among indium tin oxide (ITO), indium zinc oxide (IZO), zinc oxide (ZnO), indium oxide (In₂O₃), indium gallium oxide (IGO), or aluminum zinc oxide (AZO). When forming the sub-pixel electrode 210 as a reflective electrode, the sub-pixel electrode 210 may include a reflective layer including at least one selected from among silver (Ag), magnesium (Mg), aluminum (Al), platinum (Pt), palladium (Pd), gold (Au), nickel (Ni), neodymium (Nd), iridium (Ir), chrome (Cr), and compounds thereof. In an embodiment, the sub-pixel electrode 210 may include indium tin oxide (ITO) and silver (Ag). In an embodiment, the sub-pixel electrode 210 may include a multi-layered structure in which ITO, Ag, and ITO are sequentially.

A pixel-defining layer 113 may be on the sub-pixel electrode 210. The pixel-defining layer 113 may cover an edge region of the sub-pixel electrode 210. In embodiments, the pixel-defining layer 113 may include an opening overlapping the central portion of the sub-pixel electrode 210. The opening of the pixel-defining layer 113 may define an emission area of the light-emitting diode LED, and may further define an emission area of the sub-pixel.

The intermediate layer 220 may be on the sub-pixel electrode 210. The intermediate layer 220 may include a first functional layer 221, a second functional layer 223 on the pixel-defining layer 113, and an emission layer 222 in the opening of the pixel-defining layer 113. In an embodiment, the first functional layer 221 may be on the pixel-defining layer 113, the emission layer 222 may be in the opening of the pixel-defining layer 113 on the first functional layer 221, and the second functional layer 223 may be on the first functional layer 221 to cover the emission layer 222. In embodiments, the emission layer 222 may be in the opening of the pixel-defining layer 113 and between the first functional layer 221 and the second functional layer 223.

The emission layer 222 may include an organic emission layer including a low molecular weight material and/or a polymer material. The first functional layer 221 may include an electron transport layer (ETL) and/or an electron injection layer (EIL). The second functional layer 223 may include a hole transport layer (HTL) and/or a hole injection layer (HIL). In an embodiment, the first functional layer 221 or the second functional layer 223 may be omitted. In an embodiment, the positions of the first functional layer 221 and the second functional layer 223 may be interchanged.

The opposite electrode 230 may be on the intermediate layer 220. As an example, the opposite electrode 230 may be on the second functional layer 223. The opposite electrode 230 may cover the intermediate layer 220 entirely. The opposite electrode 230 may include a conductive material (e.g., an electrically conductive material) having a low work function. As an example, the opposite electrode 230 may include at least one selected from among silver (Ag), magnesium (Mg), aluminum (Al), platinum (Pt), palladium (Pd), gold (Au), nickel (Ni), neodymium (Nd), and iridium (Ir), chrome (Cr), lithium (Li), calcium (Ca), and an alloy thereof. The opposite electrode 230 may have a single-layered structure or a multi-layered structure.

An encapsulation layer 300 may be on the light-emitting diode LED. The encapsulation layer 300 may cover the light-emitting diode LED entirely. The encapsulation layer 300 may include at least one inorganic encapsulation layer and at least one organic encapsulation layer 320. As an example, the encapsulation layer 300 may include a first inorganic encapsulation layer 310, a second inorganic encapsulation layer 330, and an organic encapsulation layer 320. The organic encapsulation layer 320 may be between the first inorganic encapsulation layer 310 and the second inorganic encapsulation layer 330. The first inorganic encapsulation layer 310 and the second inorganic encapsulation layer 330 may include an inorganic insulating material (e.g., an inorganic electrically insulating material). As an example, the first inorganic encapsulation layer 310 and the second inorganic encapsulation layer 330 may include at least one selected from among silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂). The organic encapsulation layer 320 may include an organic insulating material (e.g., an organic electrically insulating material). As an example, the organic encapsulation layer 320 may include a polymer-based material. The polymer-based material may include a silicon-based resin, an acryl-based resin, an epoxy-based resin, polyimide, and/or polyethylene.

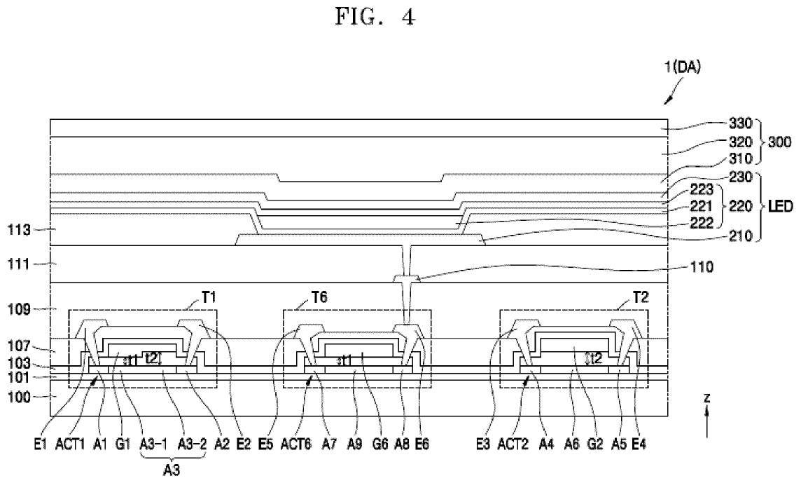

FIG. 4 is a cross-sectional view of the display apparatus according to an embodiment.

The embodiment shown in FIG. 4 is similar in overall structure to the embodiment shown in FIG. 3, but may have differences in some features. Hereinafter, the differences are mainly described.

Referring to FIG. 4, the first gate insulating layer 103 may cover each of the first active pattern ACT1, the second active pattern ACT2, and the sixth active pattern ACT6. As an example, a portion of the first gate insulating layer 103 may be on the first active pattern ACT1, another portion may be on the second active pattern ACT2, and another portion may be on the sixth active pattern ACT6. The first gate insulating layer 103 may be apart from the buffer layer 101. The portions of the first gate insulating layer 103 respectively on the active patterns may be apart from each other.

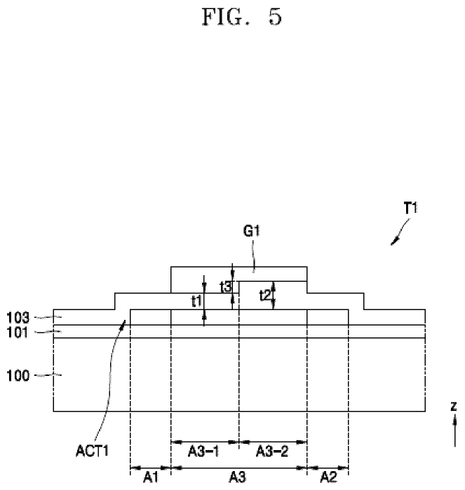

FIG. 5 is an enlarged cross-sectional view of a display apparatus according to an embodiment. FIG. 5 may be an enlarged cross-sectional view of the first transistor T1 according to an embodiment. Although FIG. 5 shows only the substrate 100, the buffer layer 101, the first active pattern ACT1, and the first gate insulating layer 103, this is for convenience of illustration and description and does not exclude other elements.

Referring to FIG. 5, the buffer layer 101 and the first active pattern ACT1 may be on the substrate 100, and the first gate insulating layer 103 may cover the first active pattern ACT1.

The first active pattern ACT1 may include the first region A1, the second region A2, the third region A3, the third-1 region A3-1, and the third-2 region A3-2 as described above. A portion of the first gate insulating layer 103 that overlaps the first region A1 or the second region A2 may have the first thickness t1. A portion of the first gate insulating layer 103 that overlaps the third-1 region A3-1 may have the first thickness t1. A portion of the second gate insulating layer 105 that overlaps the third-2 region A3-2 may have the second thickness t2. The second thickness t2 may be greater than the first thickness t1 by a third thickness t3. In embodiments, a difference between the first thickness t1 and the second thickness t2 may be the third thickness t3. In an embodiment, the third thickness t3 may be about 50 Å to about 300 Å.

In an embodiment, the first region A1 may be a source region, the second region A2 may be a drain region, and the third region A3 may be a channel region. In embodiments, the third-1 region A3-1 may be a source-side channel region, and the third-2 region A3-2 may be a drain-side channel region. In embodiments, the first gate insulating layer 103 may have a greater thickness in the drain-side channel region than in the source-side channel region.

In an embodiment, the first region A1 may be a drain region, the second region A2 may be a source region, and the third region A3 may be a channel region. In embodiments, the third-1 region A3-1 may be a drain-side channel region, and the third-2 region A3-2 may be a source-side channel region. In embodiments, the first gate insulating layer 103 may have a greater thickness in the source-side channel region than in the drain-side channel region.

In an embodiment, the concentration of hydrogen ions inside the first active pattern ACT1 may be different depending on the region. In an embodiment, the concentration of hydrogen ions inside the first active pattern ACT1 in the third-1 region A3-1 may be greater than the concentration of hydrogen ions inside the first active pattern ACT1 in the third-2 region A3-2.

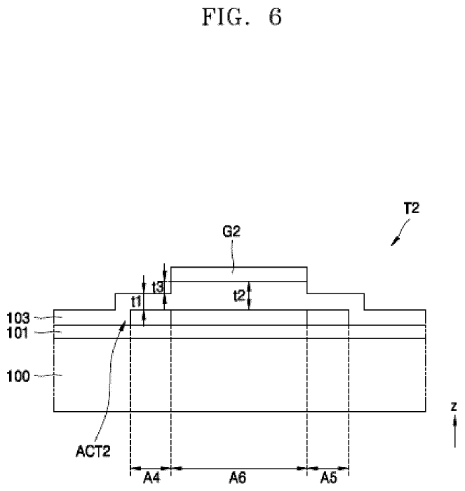

FIG. 6 is an enlarged cross-sectional view of a portion of the display apparatus according to an embodiment. FIG. 6 may be an enlarged cross-sectional view of the second transistor T2 according to an embodiment. Although FIG. 6 shows only the substrate 100, the buffer layer 101, the second active pattern ACT2, and the first gate insulating layer 103, this is for convenience of illustration and description and does not exclude other elements.

The second active pattern ACT2 may include the fourth region A4, the fifth region A5, and the sixth region A6 as described above. A portion of the first gate insulating layer 103 that overlaps the fourth region A4 may have the first thickness t1. A portion of the first gate insulating layer 103 that overlaps the fifth region A5 may have the first thickness t1. A portion of the first gate insulating layer 103 that overlaps the sixth region A6 may have the second thickness t2. In an embodiment, the fourth region A4 may be a source region (or a drain region), and the fifth region A5 may be a drain region (or a source region). In embodiments, the sixth region A6 may be a channel region. For example, the first gate insulating layer 103 may have a greater thickness in the channel region than in the source region (or drain region).

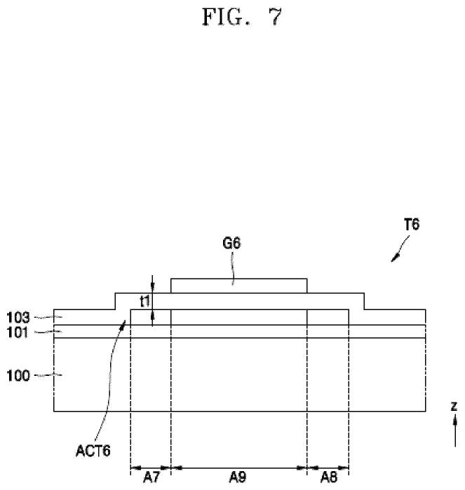

FIG. 7 is an enlarged cross-sectional view of a portion of the display apparatus according to an embodiment. FIG. 7 may be an enlarged cross-sectional view of the sixth transistor T6 according to an embodiment. Although FIG. 7 shows only the substrate 100, the buffer layer 101, the second active pattern ACT2, and the first gate insulating layer 103, this is for convenience of illustration and description and does not exclude other elements.

The sixth active pattern ACT6 may include the seventh region A7, the eighth region A8, and the ninth region A9 as described above. A portion of the first gate insulating layer 103 that overlaps the seventh region A7 may have the first thickness t1. A portion of the first gate insulating layer 103 that overlaps the eighth region A8 may have the first thickness t1. A portion of the first gate insulating layer 103 that overlaps the ninth region A9 may have the first thickness t1. In an embodiment, the seventh region A7 may be a source region (or a drain region), and the eighth region A8 may be a drain region (or a source region). In embodiments, the ninth region A9 may be a channel region. For example, the first gate insulating layer 103 may have the same thickness in the source region, the drain region, and the channel region. This is in contrast to the embodiments of the first active pattern ACT1 of the first transistor T1 shown in FIG. 5 and the second active pattern ACT2 of the second transistor T2 shown in FIG. 6, respectively.

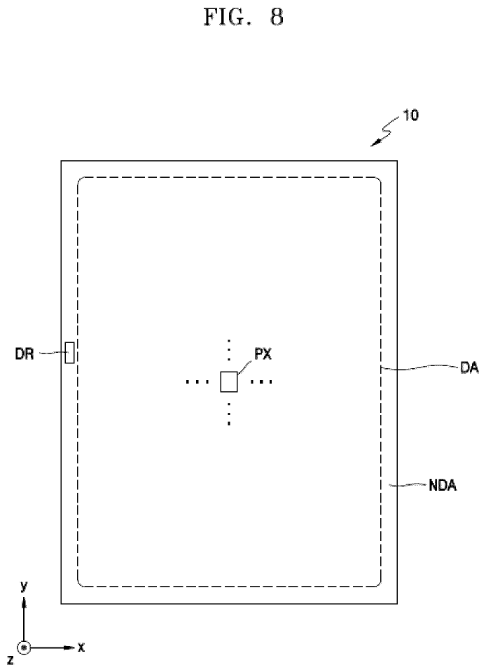

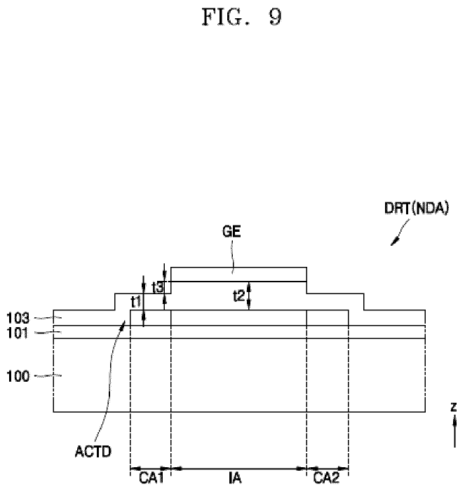

FIG. 8 is a schematic plan view of a display apparatus according to an embodiment. FIG. 9 is an enlarged cross-sectional view of a portion of a display apparatus according to an embodiment.

Referring to FIGS. 8-9, a driving circuit DR for driving the sub-pixel PX may be in the non-display area NDA of the display apparatus 10. The driving circuit DR may be connected to the sub-pixel circuit (see FIG. 2) of the sub-pixel PX. Similar to the sub-pixel circuit (see FIG. 2), the driving circuit DR may include a plurality of transistors. Similar to the first transistor T1, the second transistor T2, and the sixth transistor T6, the driving circuit transistor DRT included in the driving circuit DR may include an active pattern including a silicon semiconductor. As an example, the driving circuit transistor DRT may include a driving circuit active pattern ACTD including LTPS. The driving circuit DR may include a plurality of driving circuit transistors DRT including the driving circuit active pattern ACTD. FIG. 9 excerpts and shows (e.g., is an enlarged view showing) one of the driving circuit transistors DRT.

The driving circuit transistor DRT may include the driving circuit active pattern ACTD and a gate electrode GE. The driving circuit active pattern ACTD may include, for example, a silicon semiconductor such as LTPS. This is an example, and the disclosure does not assume that all transistors included in the driving circuit DR includes a silicon semiconductor.

The driving circuit active pattern ACTD may include a first conductive area CA1 (e.g., a first electrically conductive area CA1), a second conductive area CA2 (e.g., a second electrically conductive area CA2), and an intermediate area IA. The intermediate area IA may be between the first conductive area CA1 and the second conductive area CA2. The first conductive area CA1 and the second conductive area CA2 may have conductivity (e.g., electrical conductivity). The first conductive area CA1 may be a source region (or drain region), and the second conductive area CA2 may be a drain region (or source region). In embodiments, the intermediate area IA may be a channel region. The first conductive area CA1 and the second conductive area CA2 may be regions doped with impurities (for example, dopants).

The gate electrode GE may be over the driving circuit active pattern ACTD, wherein the gate electrode GE is insulated (e.g., electrically insulated) from the driving circuit active pattern ACTD. The gate electrode GE may overlap the intermediate area IA.

The first gate insulating layer 103 may be between the driving circuit active pattern ACTD and the gate electrode GE. A portion of the first gate insulating layer 103 that overlaps the first conductive area CA1 may have the first thickness t1. A portion of the first gate insulating layer 103 that overlaps the second conductive area CA2 may have the first thickness t1. A portion of the first gate insulating layer 103 that overlaps the intermediate area IA may have the second thickness t2. As described above, the second thickness t2 may be greater than the first thickness t1. For example, the first gate insulating layer 103 may have a greater thickness in the channel region than in the source region (or drain region).

In embodiments, the first gate insulating layer 103 may have the second thickness t2 in a channel region of at least some of a plurality of transistors of the driving circuit DR in the non-display area NDA of the display apparatus 10, and the second thickness t2 may be greater than the first thickness t1 of a source region (or drain region) of at least some of the plurality of transistors.

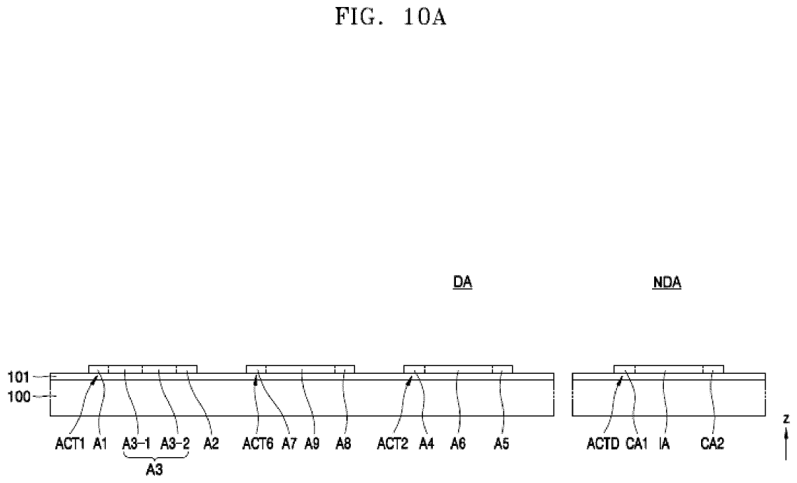

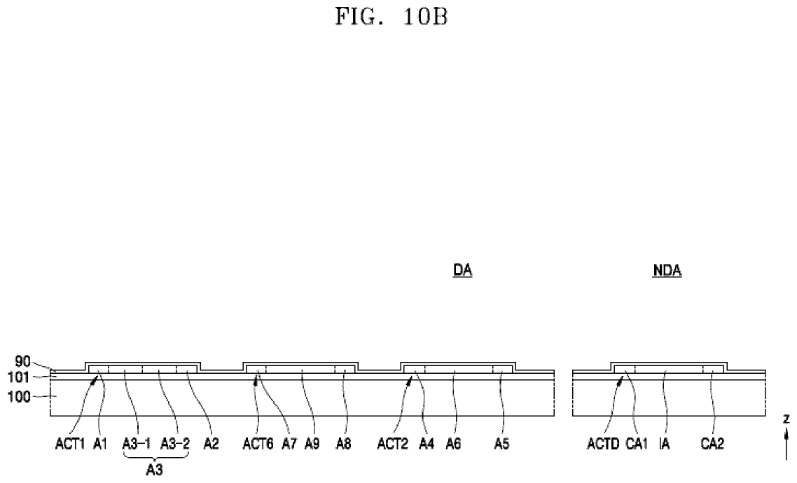

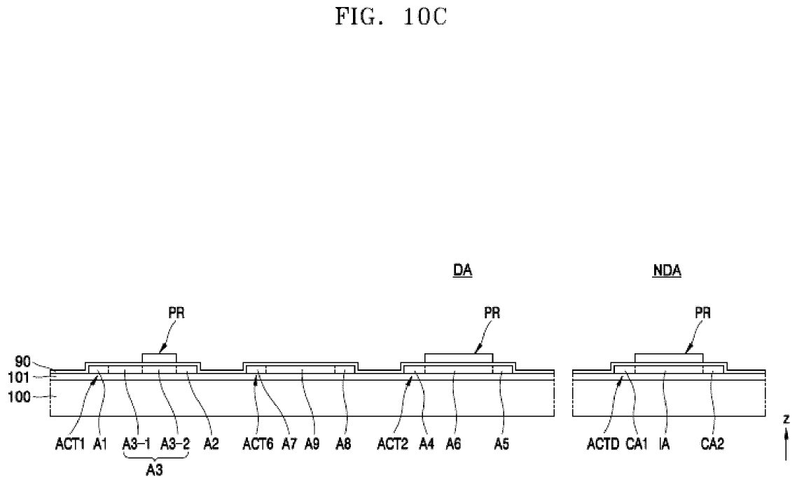

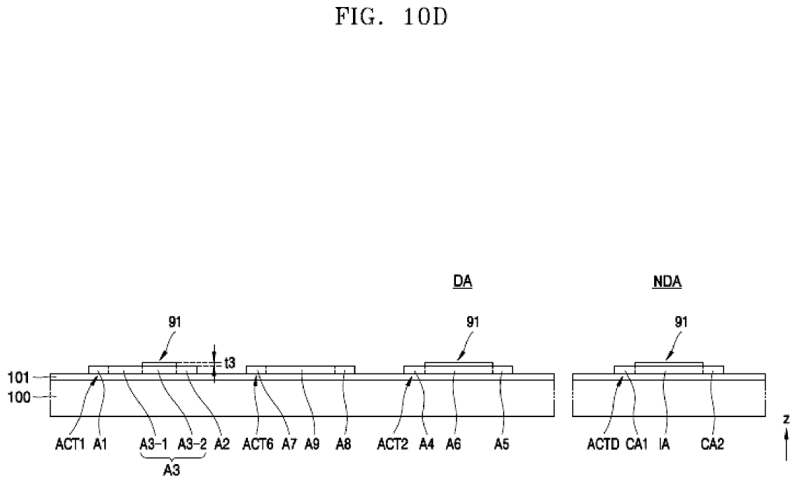

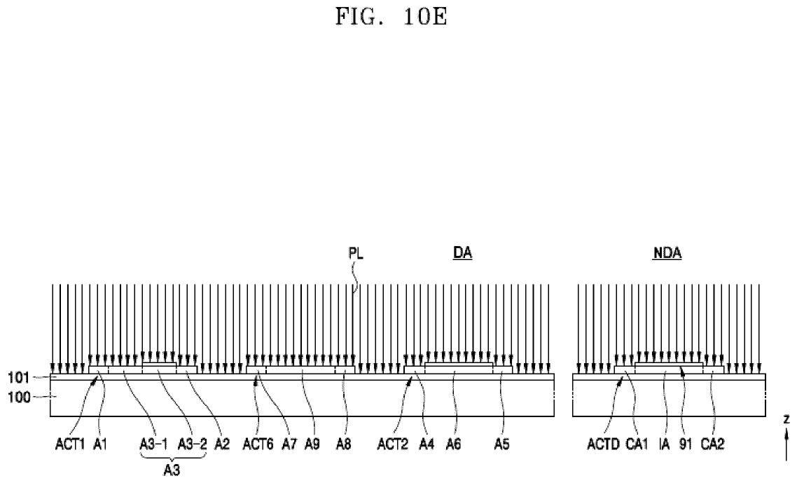

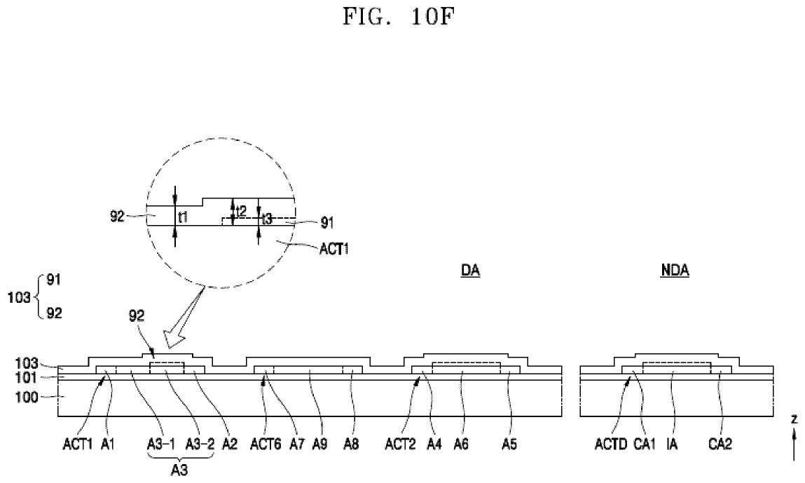

Now, a process of manufacturing the display apparatus, for example, a process of forming the first thickness t1 and the second thickness t2 of the first gate insulating layer 103 is described in more detail with reference to FIGS. 10A-10F.

FIGS. 10A, 10B, 10C, 10D, 10E, and 10F are schematic cross-sectional views showing a method of manufacturing a display apparatus, according to an embodiment.

Referring to FIG. 10A, the buffer layer 101 may be provided on the substrate 100. The first active pattern ACT1, the second active pattern ACT2, the sixth active pattern ACT6, and the driving circuit active pattern ACTD may be provided on the buffer layer 101. The first active pattern ACT1, the second active pattern ACT2, and the sixth active pattern ACT6 may be provided in the display area DA. The driving circuit active pattern ACTD may be provided in the non-display area NDA. The first active pattern ACT1, the second active pattern ACT2, the sixth active pattern ACT6, and the driving circuit active pattern ACTD may be provided on the same layer. The first active pattern ACT1, the second active pattern ACT2, the sixth active pattern ACT6, and the driving circuit active pattern ACTD may be provided substantially simultaneously.

Referring to FIG. 10B, a preliminary layer 90 may be provided on the first active pattern ACT1, the second active pattern ACT2, the sixth active pattern ACT6, and the driving circuit active pattern ACTD. The preliminary layer 90 may entirely cover the first active pattern ACT1, the second active pattern ACT2, the sixth active pattern ACT6, and the driving circuit active pattern ACTD. The preliminary layer 90 may have a thickness of about 50 Å to about 300 Å. As described below, the preliminary layer 90 may have the thickness t3 (see FIG. 10D). The preliminary layer 90 may include an inorganic insulating material (e.g., an inorganic electrically insulating material). As an example, the preliminary layer 90 may include at least one selected from among silicon oxide (SiO₂), silicon nitride (SiNₓ), and silicon oxynitride (SiON).

Referring to FIG. 10C, a photoresist PR may be provided on the preliminary layer 90. The photoresist PR may overlap the third-2 region A3-2 of the first active pattern ACT1. The photoresist PR may overlap the sixth region A6 of the second active pattern ACT2. The photoresist PR may overlap the intermediate area IA of the driving circuit active pattern ACTD.

Referring to FIGS. 10C-10D together, the preliminary layer 90 may be etched using the photoresist PR as a mask. A portion of the preliminary layer 90 that overlaps the photoresist PR may remain. The remaining portion of the preliminary layer 90 may be understood as a first insulating layer 91 (e.g., a first electrically insulating layer 91). The first insulating layer 91 may overlap the third-2 region A3-2 of the first active pattern ACT1. The first insulating layer 91 may overlap the sixth region A6 of the second active pattern ACT2. The first insulating layer 91 may overlap the intermediate area IA of the driving circuit active pattern ACTD.

The thickness of the first insulating layer 91 may be defined as the third thickness t3. Like the preliminary layer 90, the first insulating layer 91 may have a thickness of about 50 Å to about 300 Å. Like the preliminary layer 90, the first insulating layer 91 may include an inorganic insulating material (e.g., an inorganic electrically insulating material). As an example, the first insulating layer 91 may include at least one selected from among silicon oxide (SiO₂), silicon nitride (SiNₓ), and silicon oxynitride (SiON).

Referring to FIG. 10E, a passivation treatment may be performed on the embodiment shown in FIG. 10D.

The passivation treatment may be performed through plasma treatment. As shown in FIG. 10E, plasma PL may be irradiated toward the embodiment shown in FIG. 10D.

The plasma PL may reach the first activation pattern ACT1 in the first region A1, the second region A2, and the third-1 region A3-1. The plasma PL may reach the second active pattern ACT2 in the fourth region A4 and the fifth region A5. The plasma PL may reach the sixth active pattern ACT6 in the seventh region A7, the eighth region A8, and the ninth region A9 (for example, the front surface). The plasma PL may reach the driving circuit active pattern ACTD in the first conductive area CA1 and the second conductive area CA2.

The plasma PL may not sufficiently pass through the first insulating layer 91. In embodiments, the first insulating layer 91 may prevent the plasma PL from reaching a lower layer (or reduce an amount of the plasma PL that reaches a lower layer). The plasma PL may not reach the first active pattern ACT1 in the third-2 region A3-2. The plasma PL may not reach the second active pattern ACT2 in the sixth region A6. The plasma PL may not reach the driving circuit active pattern ACTD in the intermediate area IA. Accordingly, the passivation treatment may be partially performed on some active patterns. The passivation treatment may be performed on the first active pattern ACT1, the second region A2, and the third-1 region A3-1, and may not be performed on the third-2 region A3-2. The passivation treatment may be performed on the fourth region A4 and the fifth region A5 of the second active pattern ACT2, and may not be performed on the sixth region A6. In embodiments, the passivation treatment may be performed on the entire surface of the sixth active pattern ACT6. The passivation treatment may be performed on the first conductive area CA1 and the second conductive area CA2 of the driving circuit active pattern ACTD and may not be performed on the intermediate area IA.

In an embodiment, the first active pattern ACT1, the second active pattern ACT2, the sixth active pattern ACT6, and the driving circuit active pattern ACTD may include a silicon semiconductor. Dangling bonds may be present in a silicon semiconductor, for example, LTPS. When a transistor operates, some of the charge moving through the channel of the transistor may be caught or captured by the dangling bonds. In embodiments, the dangling bonds may be understood as acting as charge traps that capture charge.

The passivation treatment may remove the silicon dangling bonds. Due to the first insulating layer 91, the passivation treatment may not be performed on the third-2 region A3-2 of the first active pattern ACT1, the sixth region A6 of the second active pattern ACT2, and the intermediate area IA of the driving circuit active pattern ACTD. Accordingly, dangling bonds may remain in the third-2 region A3-2, the sixth region A6, and the intermediate area IA. Through this, when a corresponding transistor operates, charge trapping may be caused.

In an embodiment, the plasma PL may be hydrogen plasma, and the passivation may be hydrogen passivation.

The concentration of hydrogen ions inside the first active pattern ACT1 in the first region A1, the second region A2, and the third-1 region A3-1 in which the plasma PL reaches the first active pattern ACT1 may be greater than the concentration of hydrogen ions inside the first active pattern ACT1 in the third-2 region A3-2 in which the plasma PL does not reach the first active pattern ACT1.

Similarly, the concentration of hydrogen ions inside the second active pattern ACT2 in the fourth region A4 and the fifth region A5 in which the plasma PL reaches the second active pattern ACT2 may be greater than the concentration of hydrogen ions inside the second active pattern ACT2 in the sixth region A6 in which the plasma PL does not reach the second active pattern ACT2. Similarly, the concentration of hydrogen ions inside the sixth active pattern ACT6 in the ninth region A9 in which the plasma PL reaches the sixth active pattern ACT6 may be greater than the concentration of hydrogen ions inside the second active pattern ACT2 in the sixth region A6 in which the plasma PL does not reach the second active pattern ACT2.

Similarly, the concentration of hydrogen ions inside the driving circuit active pattern ACTD in the first conductive area CA1 and the second conductive area CA2 in which the plasma PL reaches the driving circuit active pattern ACTD may be greater than the concentration of hydrogen ions inside the driving circuit active pattern ACTD in the intermediate area IA in which the plasma PL does not reach the driving circuit active pattern ACTD. Similarly, the concentration of hydrogen ions inside the sixth active pattern ACT6 in the ninth region A9 in which the plasma PL reaches the sixth active pattern ACT6 may be greater than the concentration of hydrogen ions inside the driving circuit active pattern ACTD in the intermediate area IA in which the plasma PL does not reach the driving circuit active pattern ACTD.

Referring to FIG. 10F, a second insulating layer 92 may be on the embodiment shown in FIG. 10E. The second insulating layer 92 may cover the first active pattern ACT1, the second active pattern ACT2, the sixth active pattern ACT6, the driving circuit active pattern ACTD, and the first insulating layer 91.

The relationship between the first insulating layer 91 and the second insulating layer 92 is shown in more detail in an enlarged partial view within a solid line circle. The first insulating layer 91 may have the third thickness t3 as described above. The third thickness t3 may be about 50 Å to about 300 Å. The second insulating layer 92 may have the first thickness t1. The first thickness t1 may be about 1200 Å to about 1450 Å. A sum of the first thickness t1 and the third thickness t3 may be defined as the second thickness t2.

In an embodiment, the second insulating layer 92 may include an inorganic insulating material (e.g., an inorganic electrically insulating material). As an example, the second insulating layer 92 may include at least one selected from among silicon oxide (SiO₂), silicon nitride (SiNₓ), and silicon oxynitride (SiON).

In an embodiment, the first insulating layer 91 and the second insulating layer 92 may include the same material. As an example, the first insulating layer 91 and the second insulating layer 92 may include silicon oxide (SiO₂). Accordingly, although the first insulating layer 91 and the second insulating layer 92 are formed during separate processes from each other, they may be merged into one layer. As an example, after the second insulating layer 92, a border surface may not be present between the first insulating layer 91 and the second insulating layer 92. Accordingly, an interface of the first insulating layer 91 is shown as a dashed line.

After the second insulating layer 92 is provided, the first insulating layer 91 and the second insulating layer 92 may be considered as one layer, and the one layer may be defined as the first gate insulating layer 103. In embodiments, the first gate insulating layer 103 may include the first insulating layer 91 and the second insulating layer 92 that are substantially integral. Accordingly, the first gate insulating layer 103 may have the first thickness t1 in one portion and the second thickness t2 in another portion as described above.

The above-described relationship between the first insulating layer 91 and the second insulating layer 92 may be similarly applied on the second active pattern ACT2 and may also be similarly applied on the driving circuit active pattern ACTD.

Then, the display apparatus according to an embodiment may be implemented by sequentially providing the elements described above with reference to FIG. 3 on the first gate insulating layer 103.

According to an embodiment, the display apparatus is provided in which the thickness of the first gate insulating layer is different depending on a region on the channel region of the active pattern of the thin-film transistor including a silicon semiconductor. This may be because a process of covering a portion of the channel region with a layer including the same material as a material of the first gate insulating layer is included in the process of manufacturing the display apparatus. A portion of the channel region may be covered by the layer and the passivation treatment may be performed. After the passivation treatment, the active pattern of the channel region may have different properties depending on the position thereof.

As an example, because the plasma (e.g., hydrogen plasma) performing passivation may not pass through the portion of the channel region covered by the layer, the passivation may be relatively less performed. In embodiments, silicon dangling bonds present in the silicon semiconductor of the active pattern may not be sufficiently removed from the relevant region. Accordingly, when driving the thin-film transistor, charge trap due to dangling bonds may occur. This may lead to an increase in the amount of charge trapped within the channel region, and the increase in the amount of charge may contribute to controlling afterimages in display apparatuses and threshold voltages in thin film transistors.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various suitable changes in form and details may be made therein without departing from the spirit and scope as defined by the following claims, and equivalents thereof.

What is claimed is:

1. A display apparatus comprising:
a substrate;
a first transistor on the substrate and comprising a first active pattern comprising a silicon semiconductor; and
a gate insulating layer on the first active pattern,
wherein the first active pattern comprises a first region, a second region, and a third region between the first region and the second region, the third region comprises a third-1 region adjacent to the first region and a third-2 region adjacent to the second region, and
a first thickness of a portion of the gate insulating layer that overlaps the third-1 region is less than a second thickness of another portion of the gate insulating layer that overlaps the third-2 region.

2. The display apparatus of claim 1, further comprising a first gate electrode on the gate insulating layer and that overlaps the third region of the first active pattern.

3. The display apparatus of claim 2, wherein a thickness of a portion of the first gate electrode that overlaps the third-1 region is greater than a thickness of another portion of the first gate electrode that overlaps the third-2 region.

4. The display apparatus of claim 1, further comprising a second transistor on the substrate and comprising a second active pattern comprising a silicon semiconductor,
wherein the second active pattern comprises a fourth region, a fifth region, and a sixth region between the fourth region and the fifth region, the gate insulating layer overlaps the second active pattern, and a portion of the gate insulating layer that overlaps the sixth region has the second thickness.

5. The display apparatus of claim 1, further comprising a third transistor on the substrate and comprising a third active pattern comprising a silicon semiconductor,
wherein the third active pattern comprises a seventh region, an eighth region, and a ninth region between the seventh region and the eighth region, and
the gate insulating layer overlaps the third active pattern, and a portion of the gate insulating layer that overlaps the ninth region has the first thickness.

6. The display apparatus of claim 1, further comprising a light-emitting diode on the gate insulating layer, wherein the second region of the first active pattern is connected to the light-emitting diode.

7. The display apparatus of claim 1, wherein a concentration of hydrogen ions inside the first active pattern in the third-1 region is greater than a concentration of hydrogen ions inside the first active pattern in the third-2 region.

8. The display apparatus of claim 1, wherein the substrate comprises a display area and a non-display area surrounding the display area, the first transistor is in the display area, the display apparatus comprises at least one driving circuit transistor in the non-display area and comprising a driving circuit active pattern comprising a silicon semiconductor, and the gate insulating layer partially has the second thickness in a region that overlaps the driving circuit active pattern of the driving circuit transistor.

9. The display apparatus of claim 8, wherein the driving circuit active pattern of the driving circuit transistor comprises a first conductive area, a second conductive area, and an intermediate area between the first conductive area and the second conductive area, and the gate insulating layer has the second thickness in a region that overlaps the intermediate area.

10. An electronic apparatus comprising:
a display apparatus; and
a housing accommodating the display apparatus,
wherein the display apparatus comprises:
a substrate;
a first transistor on the substrate and comprising a first active pattern comprising a silicon semiconductor; and
a gate insulating layer on the first active pattern,
wherein the first active pattern comprises a first region, a second region, and a third region between the first region and the second region, the third region comprises a third-1 region adjacent to the first region and a third-2 region adjacent to the second region, and
a first thickness of a portion of the gate insulating layer that overlaps the third-1 region is less than a second thickness of another portion of the gate insulating layer that overlaps the third-2 region.

11. A method of manufacturing a display apparatus, the method comprising:
providing, on a substrate, a first active pattern comprising a first region, a second region, and a third region between the first region and the second region;
providing a first insulating layer on the first active pattern in a third-2 region of a third-1 region adjacent to the first region and the third-2 region adjacent to the second region; and
passivation-treating the first active pattern in the third-1 region.

12. The method of claim 11, further comprising forming a gate insulating layer by providing a second insulating layer on the first active pattern, wherein the gate insulating layer comprises the first insulating layer and the second insulating layer, the gate insulating layer has a first thickness in the third-1 region, and the gate insulating layer has a second thickness in the third-2 region.

13. The method of claim 12, wherein the second insulating layer has the first thickness, the first insulating layer has a third thickness, and the second thickness is a sum of the first thickness and the third thickness.

14. The method of claim 12, wherein the first insulating layer and the second insulating layer comprise a same material.

15. The method of claim 11, further comprising providing, on the substrate, a second active pattern comprising a fourth region, a fifth region, and a sixth region between the fourth region and the fifth region, wherein the first insulating layer overlaps the sixth region of the second active pattern.

16. The method of claim 11, wherein the providing of the first insulating layer comprises:
providing a preliminary layer to cover the first active pattern entirely;
providing a photoresist to overlap the third-2 region; and
etching the preliminary layer using the photoresist as a mask.

17. The method of claim 11, wherein the passivation-treating of the first active pattern comprises irradiating hydrogen plasma toward the first active pattern,
wherein the first insulating layer prevents the hydrogen plasma from reaching the first active pattern in the third-2 region.

18. The method of claim 11, wherein, after the passivation-treating of the first active pattern is performed, a concentration of hydrogen ions inside the first active pattern in the third-1 region is greater than a concentration of hydrogen ions inside the first active pattern in the third-2 region.

19. The method of claim 11, wherein the substrate comprises a display area and a non-display area surrounding the display area, the first active pattern is in the display area, and the method further comprises providing a driving circuit active pattern comprising a silicon semiconductor in the non-display area,
wherein the first insulating layer at least partially overlaps the driving circuit active pattern.

20. The method of claim 11, further comprising forming a light-emitting diode on the substrate, wherein the light-emitting diode is electrically connected to the second region of the first active pattern.
